(19) United States
(12) Patent Application Publication
(10) Pub. No.: US 2025/0015223 A1
(43) Pub. Date: Jan. 9, 2025

(54) METHOD AND WET BENCH FOR THE IN-LINE PROCESSING OF SOLAR-CELL SUBSTRATES

(71) Applicant: SINGULUS TECHNOLOGIES AG, Kahl am Main (DE)

(72) Inventors: Philipp NOACK, Maisach (DE); Mirza CORDA, Maisach (DE); Benjamin MANDLMEIER, Pöcking (DE); Bianca WATTENBERG, Alling (DE)

(73) Assignee: SINGULUS TECHNOLOGIES AG, Kahl am Main (DE)

(21) Appl. No.: 18/705,688

(22) PCT Filed: Nov. 21, 2022
(86) PCT No.: PCT/EP2022/082652

§ 371 Date: Apr. 29, 2024

(30) Foreign Application Priority Data
Nov. 23, 2021 (DE) 10 2021 130 667.1
Feb. 22, 2022 (DE) 10 2022 104 191.3

(51) Int. Cl. H01L 31/18; H01L 21/67; H01L 21/677

(52) U.S. Cl. CPC H01L 31/1876; H01L 21/67086; H01L 21/67173; H01L 21/67248; H01L 21/6776

(57) ABSTRACT

A method and a wet bench for processing a plurality of solar cell substrates are described. Each solar cell substrate includes a silicon wafer. The method includes steps of removing at least a partial area of a near-surface layer of the silicon wafer by an etching process by treating the surface of the solar cell substrate with an etching liquid, and producing a silicon oxide thin film at least on a partial surface of the solar cell substrate by treating the partial surface with an oxidising liquid. The solar cell substrates are subjected to process steps (i) and (ii) sequentially, one after the other within a single processing apparatus. The wet bench usable for etching liquid baths as well as oxidation liquid baths in which the solar cell substrates may be superficially oxidised, for example in an ozone-containing solution.

### FIELD

The present invention relates to a method and a wet bench which may be used in processing solar cell substrates.

### BACKGROUND

Solar cells are used to convert light directly into electrical energy using the photovoltaic effect. For this purpose, a solar cell has a solar cell substrate with a semiconductor substrate and contact structures disposed thereon.

A variety of processing methods have been developed for manufacturing solar cells with the highest possible efficiency at the lowest possible cost. In one of these processing methods, passivated contacts are formed on the surface of the semiconductor substrate. A solar cell concept furnished with such passivated contacts is also referred to as the TOPCon solar cell concept. A passivated contact may be charge carrier-selective, that is to say, for example, it may allow negative charge carriers (electrons) to pass more readily than positive charge carriers (holes) or vice versa. This may reduce recombination losses on the surface of the semiconductor substrate, which may increase the efficiency of the solar cell. For this purpose, the passivated contact comprises a very thin dielectric layer, for example in the form of an oxide layer, through which charge carriers may partially tunnel and which is therefore also referred to as a tunnel layer or tunnel oxide layer. On one surface, this tunnel oxide layer adjoins the semiconductor substrate. On an opposite surface, the tunnel oxide layer adjoins an electrically conductive contact layer, for example a metal layer, a polycrystalline silicon layer also being usually disposed between the tunnel oxide layer and the electrically conductive contact layer. A quality of such a passivated contact is significantly influenced by a quality of the tunnel oxide layer, in particular by its thickness, homogeneity and/or purity, especially the purity of the silicon surface on which the tunnel oxide is to be formed.

Various processing sequences are known for producing TOPCon solar cells. A silicon wafer is normally used as the solar cell substrate. A doped emitter layer and a silicate glass layer covering the emitter layer are usually formed on its surface. For example, the silicon wafer may be exposed to a dopant-containing atmosphere at high temperatures. On the one hand, dopant such as boron or phosphorus is diffused into the surface of the silicon wafer to form the doped emitter layer. On the other hand, a dopant-containing silicate glass layer, that is to say, for example, a borosilicate glass layer (BSG) or a phosphosilicate glass layer (PSG), is formed on the surface of the silicon wafer. The doped emitter layer may extend along the entire surface of the silicon wafer. The silicate glass layer usually covers the entire emitter layer. After the emitter layer has been formed over the entire surface, it typically has to be removed from certain areas in order to furnish an underlying base area of the silicon wafer with electrical contacts without causing electrical short circuits with the emitter layer or with electrical contacts to be provided there. For this purpose, in most conventional solar cell concepts, the emitter layer is removed at least along edges of the silicon wafer or preferably along the whole underside of the silicon wafer, including possibly the edges, therefore this process is often referred to as the edge isolation process. Following such an edge isolation process, to then form the passivated contacts, a thin dielectric layer may first be produced as a tunnel oxide layer at desired positions on the surface of the solar cell substrate, before this layer is contacted by forming the electrically conductive contact layer.

In another processing method, a tunnel oxide layer is formed on the surface of the semiconductor substrate and then covered by a layer of polycrystalline silicon. This solar cell concept is also known as the POLO solar cell concept (polycrystalline silicon on oxide). In the manufacture of POLO solar cells, a silicon wafer is generally first freed from a possibly saw-damaged outer layer by means of an etching step, then a thin oxide layer is produced on the surface of the silicon wafer, on which a thin poly-Si layer is then deposited at least in some areas.

It is pointed out that, in the following, reference is made predominantly to the production of solar cells based on the TOPCon concept, the explanations being merely exemplary and the described features and characteristics also being usable in the context of other types of solar cell production, in particular for the production of POLO solar cells.

### SUMMARY

For an implementation of, for example, the TOPCon solar cell concept or the POLO solar cell concept on an industrial scale, an aim may be to ensure that the processing sequence to be used has as many similarities as possible with processing sequences that have been used industrially to date, such as those used in the production of PERC (Passivated Emitter and Rear Contact) solar cells, which have dominated the manufacture of solar cells on an industrial scale in recent years.

This means, among other things, that equipment or entire production lines need only to be slightly modified in order to be able to produce TOPCon solar cells instead of PERC solar cells. Another aim may be to ensure that a processing method used, for example, to implement the TOPCon solar cell concept, may be established as simply, cost-effectively and/or process-stably as possible. A further aim may be to ensure that apparatus used for this purpose, such as a wet bench in particular, may be provided simply, cost-effectively and/or reliably.

The said requirements may be fulfilled, at least in part, with the subject-matter of one of the independent claims of the present application. Advantageous embodiments are indicated in the dependent claims and the following description.

According to a first aspect of the present invention, a method for processing a plurality of solar cell substrates is described. Each solar cell substrate comprises a silicon wafer. The method comprises at least the following process steps, preferably in the order given:
(i) removing at least a partial area of a near-surface layer of the silicon wafer by means of an etching process by treating the surface of the solar cell substrate with an etching liquid, and
(ii) producing a silicon oxide thin film at least on a partial surface of the solar cell substrate by treating the partial surface with an oxidising liquid.

The solar cell substrates are subjected to process steps (i) and (ii) sequentially, one after the other within a single processing apparatus.

According to a second aspect of the present invention, a wet bench for processing solar cell substrates is described, the wet bench being configured to carry out or control the method according to an embodiment of the first aspect of the invention. For this purpose, the wet bench may in particular comprise an etching assembly with at least one etching liquid bath, an oxidation assembly with at least one oxidation liquid bath, and a conveyor device. The etching assembly comprises at least one etching liquid bath for receiving at least one etching liquid by means of which at least a partial area of a near-surface layer of a silicon wafer is to be removed by means of an etching process by treating the surface of the solar cell substrate with an etching liquid in an etching process. The oxidation assembly comprises at least one oxidation liquid bath for receiving at least one oxidising liquid, by means of which a silicon oxide thin film is to be produced at least on a partial surface of the solar cell substrate by treating the partial surface with the oxidising liquid in an oxidation process. The conveyor device is configured to move the silicon substrates one after the other, first through the etching assembly and then through the oxidation assembly.

Embodiments of the invention may be considered, inter alia and without limiting the invention, as being based on ideas or findings described below:

By way of introduction, a basic idea concerning embodiments of the invention described herein will be briefly explained, this explanation to be interpreted as merely roughly summarising and not limiting the invention:

As already mentioned, it is aimed to implement a partial sequence of process steps as simply, cost-effectively and/or process-stably as possible, particularly in the manufacture of solar cells. At least two functionalities are to be implemented within the scope of this partial sequence: On the one hand, on a solar cell substrate which has an emitter layer and a silicate glass layer covering the emitter layer in a near-surface layer as a result of previous process steps, for example in order to produce TOPCon solar cells, an etching process is to be carried out in which a partial area of the near-surface layer is removed by etching. On the other hand, a silicon oxide thin film is to be produced on a partial surface of the solar cell substrate, which may then serve as a tunnel oxide layer of a passivated contact, for example, in order to ultimately manufacture the TOPCon solar cell, for example. Conventionally or on a laboratory scale, the two functionalities mentioned above are implemented using processes wherein the process steps are carried out in different sets of processing apparatus. However, as explained in more detail below, it has now been recognised that positive effects may be achieved if the process steps for implementing both functionalities are carried out within a single processing apparatus. For this purpose, the solar cell substrates should be subjected in a track to the process steps sequentially one after the other in the common processing apparatus, with possibly a plurality of solar cells being moved simultaneously along a plurality of parallel tracks. Such a procedure is also referred to as in-line processing. In contrast to processing methods in which a large number of substrates undergo a process step at the same time, that is to say, so-called batch processes, such in-line processing allows simple and process-stable implementation of both functionalities in a common processing apparatus for carrying out the edge isolation process and generating the silicon oxide thin film. Furthermore, as explained in more detail below, disadvantages observed when implementing the different functionalities in separate processing devices may be avoided. In particular, it is possible to avoid uncontrolled formation of oxides on the surface of the solar cell substrates during transport of the solar cell substrates between the separate processing devices or during intermediate storage of the solar cell substrates, which could have a detrimental effect on subsequent formation of the silicon oxide thin film and its passivation effect and thus ultimately on the efficiencies of manufactured solar cells. As a common processing apparatus, a wet bench may be used having both an etching assembly and an oxidation assembly, wherein the solar cell substrates are moved by a conveyor device successively, that is to say, “in-line”, through both assemblies in order to effect edge isolation and subsequent generation of the silicon oxide thin film.

Possible features of embodiments of the invention and advantages to be achieved thereby are described in detail below.

The processing method described herein and the processing apparatus used to carry it out should preferably be configured in such a way that they may be integrated without undue effort into industrially usable processing methods for manufacturing wafer-based silicon solar cells or into process lines used for this purpose. In particular, it is aimed to be able to use the described processing method and processing apparatus in the manufacture of new types of solar cell concepts, such as the TOPCon concept in particular, and to be able to continue to use many of the processing steps or equipment that have previously been tested and used in the manufacture of conventional solar cell concepts, either unchanged or with only minor modifications.

In the manufacture of wafer-based silicon solar cells, a solar cell substrate is first provided in the form of a silicon wafer. This may have, for example, a thickness of between 50 μm and 500 μm and an area of 100×100 mm² or more. The silicon wafer may be made of monocrystalline, multicrystalline or polycrystalline silicon. The silicon wafer may be doped with a base doping of p-type dopants such as, for example, elements of the third main group such as boron or gallium, or of n-type dopants such as, for example, elements of the fifth main group such as phosphorus. The silicon wafer may possibly be pre-treated, for example by removing a saw damage by etching and/or cleaning its surface. Alternatively, a saw damage may be removed using the etching process of the first process step of the method described herein.

Subsequently, according to one embodiment, which is particularly suitable for the production of TOPCon solar cells, an emitter layer is produced on a surface of the silicon wafer on one or both sides of the wafer. In industrial manufacturing processes, the silicon wafer is usually placed in a dopant-containing atmosphere for this purpose. This atmosphere contains dopants which result in doping opposite to the base doping. The atmosphere is kept at very high temperatures, typically above 700° C., often above 850° C. This atmosphere usually also contains oxygen. Under these process conditions, a dopant-containing silicate glass layer then forms on the surface of the silicon wafer. From this layer, dopants successively diffuse into an area of the silicon wafer near the surface, thereby forming the emitter layer. Both the emitter layer and the silicate glass layer are usually very thin compared to the thickness of the silicon wafer and typically have a layer thickness of a few micrometres at most, often less than 1 μm.

The emitter layer formed in this way and the silicate glass layer lying above it cover the entire surface of the silicon wafer. However, to be able subsequently to achieve contact with not only the outer emitter layer but also the underlying base area of the solar cell substrate, partial areas of the emitter layer and of the silicate glass layer must be removed as part of an edge isolation process. In principle, various process technologies are known for this purpose. On an industrial scale, a technique is predominantly used wherein the aforementioned partial areas are removed by etching in an etching solution. The solar cell substrate may be processed in a wet bench in which suitable etching processes are carried out by at least partially immersing the solar cell substrate in one or more etching solutions contained in baths of the wet bench.

In an approach that is often conventionally used, the silicate glass layer and the underlying emitter layer are removed in the partial areas to be removed for example by treatment with a toxic and/or environmentally harmful etching solution containing both hydrofluoric acid (HF) and nitric acid (HNO₃). The solar cell substrates may be held or moved in such a way that only one of their opposite main surfaces comes into contact with the etching solution and is thereby freed of the silicate glass layer and the emitter layer.

After such an etching process, for edge isolation in conventional processing the solar cell substrate is usually first rinsed in deionised water and then dried so that it is no longer wetted by the etching solution. The solar cell substrate may then be processed further, for example to form electrical contacts on its surfaces.

As mentioned at the outset, in modern solar cell concepts such as the TOPCon concept such electrical contacts may be configured as passivated contacts. For this purpose, a thin dielectric layer must be formed as a tunnel layer between the surface of the solar cell substrate and an electrically conductive contact layer. This is usually formed as a tunnel oxide layer with a silicon oxide thin film having a thickness of a few nanometres, that is to say, for example, less than 10 nm, preferably less than 5 nm.

Various concepts have been developed or considered to form this tunnel oxide layer. For example, a large number of solar cell substrates may together undergo an oxidation process after edge isolation has been carried out on them. An oxidising liquid, an oxidising gas or an oxidising plasma, possibly at significantly increased temperatures, may be used for oxidation. Alternatively, the large number of solar cell substrates may be coated with an oxide layer on an exposed surface in a common process step. Deposition processes such as chemical vapour deposition (CVD), in particular LPCVD (low pressure CVD), APCVD (atmospheric pressure CVD) or PECVD (plasma enhanced CVD), may be used for coating.

Common to all these concepts, however, is that many solar cell substrates are furnished with the tunnel oxide layer together, that is to say, in a batch process. The solar cell substrates are previously subjected to the edge isolation process sequentially, that is to say, one after the other, in the wet bench. Consequently, the solar cell substrates generally have to be cleaned and dried first, then collected and stored temporarily before undergoing further processing together with other solar cell substrates in another apparatus to form the tunnel oxide layer.

It has been observed that, during drying and/or subsequent storage, a thin, undefined oxide layer may form on the surface of the solar cell substrates as soon as it comes into contact with oxygen, especially in contact with ambient air. It has been recognised that the oxide layer formed in this uncontrolled manner may have detrimental properties and/or may adversely influence the formation of the tunnel oxide layer to be subsequently formed in a controlled manner. To avoid such adverse influences, drying and/or storage of the solar cell substrates may be carried out in an inert gas atmosphere, for example a nitrogen atmosphere. However, this may significantly increase operating costs. Alternatively, the uncontrollably formed oxide layer may be selectively removed prior to forming the tunnel oxide layer, but this generally leads to additional process effort, for example at least three steps comprising etching of the oxide with HF, rinsing and nitrogen drying, and associated costs.

In order to avoid in particular the described disadvantages of conventional concepts, it is therefore proposed to carry out the edge isolation process and the production of the silicon oxide thin film for the formation of passivated contacts within a single processing apparatus. The processing apparatus may be configured as a wet bench. The solar cell substrates are to be treated sequentially along one or more tracks, one after the other, first with an etching liquid to remove a partial area of the emitter layer and the silicate glass layer. The solar cell substrates are then to be treated in the same processing apparatus and also sequentially, one after the other, with an oxidising liquid to produce the silicon oxide thin film. The two process steps should follow each other directly in the processing apparatus, that is to say, they should be carried out in-line. As described in more detail below, further process steps, in particular rinsing, cleaning or etching steps, may be carried out before, between or after the process steps mentioned.

In this case, a wet bench usable as a processing apparatus has both an etching assembly and an oxidation assembly. As part of the process described herein, in order to carry out the etching step, the etching assembly is adapted to remove the partial area of the near-surface layer of the silicon wafer including any emitter layer and silicate glass layer previously produced there. The oxidation assembly is adapted to produce the silicon oxide thin film as part of the process described herein.

In the etching assembly, at least one etching liquid bath is provided which may contain an etching liquid by means of which the near-surface layer of the silicon wafer may be etched back. According to one embodiment, at least two etching liquid baths are provided in the etching assembly which may contain etching liquids by means of which the emitter layer and/or the silicate glass layer may be removed by etching as part of the etching process, which may also act as an edge isolation process.

Specifically, according to one embodiment of the invention, the etching assembly may comprise an etching liquid bath configured to receive an etching liquid containing hydrofluoric acid. The wet bench may further comprise parameterisation devices configured to adjust process parameters relating to the etching liquid containing hydrofluoric acid in the etching liquid bath within predetermined ranges during the etching process.

In other words, the etching liquid bath may be configured to resist the etching liquid containing hydrofluoric acid, for example because of the materials used for its components. Furthermore, parameterisation devices may be provided in the wet bench whereby it is possible to adjust process parameters that influence the etching process effected by the etching liquid. Such process parameters may be, for example, a concentration of the etching liquid, a temperature of the etching liquid, a homogeneity of the etching liquid, etc. To adjust the concentration, for example, a parameterisation device in the form of one or more dosing devices may be provided, by means of which highly concentrated etching liquid and/or solvent may be added to the etching liquid contained in the etching liquid bath. If necessary, concentration measuring sensors may be provided in order to measure the concentration of the etching liquid in one or more areas of the etching liquid bath. The concentration of the etching liquid may be determined, for example, by measuring the electrical conductivity. To adjust the temperature, for example, a parameterisation device may be provided in the form of one or more tempering devices, such as heating devices or cooling devices, by means of which the etching liquid contained in the etching liquid bath may be heated or cooled. If necessary, temperature measuring sensors may be provided in order to measure the temperature of the etching liquid in one or more areas of the etching liquid bath. To influence the homogeneity of the etching liquid, a parameterisation device in the form of one or more mixing devices may be provided, by means of which the etching liquid may be mixed in the etching liquid bath.

In the oxidation assembly, at least one oxidation liquid bath is provided which may contain an oxidising liquid by means of which the silicon oxide thin film may be generated on the partial surface of the solar cell substrate.

Specifically, according to one embodiment of the invention, the oxidation assembly may comprise at least one oxidation liquid bath configured to receive the oxidising liquid. The wet bench may further include parameterisation devices configured to adjust process parameters relating to the oxidising liquid in the oxidation liquid bath during the oxidation process within predetermined ranges.

In other words, the oxidation liquid bath may be configured to resist the oxidising liquid, for example, because of the materials used for its components. Furthermore, parameterisation devices may be provided in the wet bench whereby it is possible to adjust process parameters that influence the oxidation process effected by the oxidising liquid. Such process parameters may be, for example, a concentration of the oxidising liquid, a temperature of this liquid, a homogeneity of this liquid, etc. To adjust the concentration, for example, a parameterisation device in the form of one or more dosing devices may be provided, by means of which an oxidising agent and/or solvent may be added to the liquid contained in the oxidation liquid bath. If necessary, concentration measuring sensors may be provided in order to measure the concentration of the oxidising liquid in one or more areas of the oxidation liquid bath. To adjust the temperature, for example, a parameterisation device may be provided in the form of one or more tempering devices, such as heating devices or cooling devices, by means of which the liquid contained in the oxidation liquid bath may be heated or cooled. If necessary, temperature measuring sensors may be provided in order to measure the temperature of the liquid in one or more areas of the oxidation liquid bath. To influence the homogeneity of the oxidising liquid, a parameterisation device in the form of one or more mixing devices may be provided, by means of which the liquid may be mixed in the oxidation liquid bath.

Due to the fact that the wet bench comprises both the etching assembly with the at least one etching liquid bath and the oxidation assembly with the at least one oxidation liquid bath, the solar cell substrates may successively pass within the same processing device through the first process step (i) for surface back-etching or edge isolation and then the second process step (ii) for producing the silicon oxide thin film.

According to one embodiment of the invention, solar cell substrates are moved one after the other by means of a common conveyor device of the processing apparatus, first through the etching liquid bath containing the etching liquid and then through the oxidation liquid bath containing the oxidising liquid.

In other words, the wet bench preferably has a single conveyor device, for example with a plurality of driven transport rollers, which transport the solar cell substrates along a displacement path. The conveyor device is configured and runs along both the etching liquid bath and the oxidation liquid bath in such a way that solar cell substrates transported by the conveyor device are first moved through the etching liquid in the etching liquid bath and then through the oxidising liquid in the oxidation liquid bath. The solar cell substrates may be fully immersed in the respective liquid so that the entire surface of a substrate is wetted. Alternatively, only a partial surface of the solar cell substrates may be brought into contact with the respective liquid, so that only this partial surface is wetted. By means of the conveyor device, a continuous process or an in-line process may be established whereby the first and second process steps of the method described herein are carried out automatically one after the other.

According to one embodiment, during the process steps (i) and (ii), solar cell substrates may be moved at a uniform speed first through the etching liquid and then through the oxidising liquid.

In other words, the speed at which the solar cell substrates pass through the etching assembly and the speed at which the solar cell substrates pass through the oxidation assembly should be the same. This may be achieved, for example, by moving the solar cell substrates through both assemblies with a common conveyor device. For example, the driven transport rollers of a conveyor device may be coupled with each other and accordingly rotate in a synchronised fashion. Alternatively, separate conveyor devices may be provided in the two assemblies, but synchronised with regard to their conveying speeds. Accordingly, a throughput of solar cell substrates through each of the two assemblies may be the same and equal to the overall throughput of the wet bench. Waiting times and/or storage times during which solar cell substrates could oxidise uncontrollably, for example through contact with ambient air, after the etching process has been carried out, may thus be largely eliminated.

In an alternative embodiment, the solar cell substrates may be moved at different speeds through the etching liquid on the one hand and through the oxidising liquid on the other. For this purpose, separate conveyor devices may be provided in the wet bench in different areas or baths. Throughput in the different areas or baths may be standardised by having the conveyor device transport the solar cell substrates for example with different distances between solar cell substrates disposed one after the other.

According to one embodiment, the solar cell substrates may remain wetted with liquid at least in some areas during a transfer from process step (i) to process step (ii).

In other words, the solar cell substrates may be transferred from the etching liquid bath to the oxidation liquid bath in a completely or at least partially wetted state. It is true that, because the surface of the solar cell substrate may acquire hydrophobic properties as a result of the treatment in process step (i), partial dewetting may occur as soon as the solar cell substrate is moved out of the etching liquid bath. As a rule, however, complete dewetting will not occur despite these hydrophobic properties, but rather at least a small residue of liquid will wet the solar cell substrate. In particular, with the method proposed here and with the wet bench used for this purpose, no active dewetting and/or drying of the solar cell substrates needs to take place during the transfer from process step (i) to process step (ii). In particular, there is no need to use a so-called air knife, that is to say, gas circulated under pressure, to carry out drying or dewetting between the two process steps (i) and (ii). Transfer of a solar cell substrate between the two baths may preferably take place very quickly, for example within less than 1 minute, preferably less than 30 seconds or even less than 10 seconds. In other words, between passing through the etching assembly and passing through the oxidation assembly, the solar cell substrates do not need to be dried in the interim. The risk of uncontrolled oxidation occurring on the surface of the solar cell substrates, for example through contact with ambient air, may therefore be minimised.

According to one embodiment, in process step (ii), the silicon oxide thin film may be produced on the partial surface of the solar cell substrate by treating the partial surface with an ozone-containing solution.

In other words, an ozone-containing solution may be used as the oxidising liquid. Ozone (O₃) may have a strong oxidising effect so that, for example, silicon oxide is formed on contact with silicon, for example as silicon dioxide (SiO₂) or as non-stoichiometric silicon oxide (SiOₓ). Ozone may dissolve in a liquid in substantial concentrations. For example, water, in particular deionised water, may serve as a solvent. A small amount of acid, in particular hydrochloric acid, may be added to the water, for example to increase the ozone solubility. By means of the ozone-containing solution, the surface of the silicon wafer may thus be efficiently and uniformly oxidised to produce the silicon oxide thin film.

According to one embodiment, the wet bench may further comprise an ozone generator configured to enrich the oxidising liquid with ozone.

Using such an ozone generator, a strongly oxidising liquid may be produced in a relatively simple and/or easily controlled manner. The ozone generator may, for example, form gaseous ozone from oxygen contained in the ambient air or oxygen supplied from a gas supply device, possibly with the addition of small amounts of nitrogen. This ozone may then be enriched in a solvent with suitable process parameters, in particular suitable temperatures and pressures, in order to form the oxidising liquid.

According to one embodiment, the ozone-containing solution may have an ozone concentration of between 0.1 ppm and 70 ppm, preferably between 1 ppm and 40 ppm, and more preferably between 25 ppm and 40 ppm.

In particular, ozone-containing solutions with a high ozone content of, for example, more than 25 ppm may serve as strongly oxidising liquids. It is true that forming such highly concentrated ozone-containing solutions may require some technical effort and/or an adherence to particular process parameters. However, in order to produce the silicon oxide thin film suitably, for example in a sufficiently short time, within the scope of the process proposed herein, the necessary technical effort or suitable control of the process parameters may be justified.

According to one embodiment, the ozone-containing solution may have a temperature of between 0° C. and 60° C., preferably between 20° C. and 50° C. and more preferably between 30° and 45° C.

In other words, it has been found advantageous to adjust the ozone-containing solution to relatively low temperatures during the production of the silicon oxide thin film. On the one hand, the process temperature of the ozone-containing solution influences a concentration at which ozone may be dissolved in the solvent, wherein, in general, the lower the temperature of the solution, the higher the ozone concentration that may be achieved and kept stable. On the other hand, the process temperature may influence the reaction rate at which an oxidation reaction occurs, with reaction rates generally increasing with temperature. Overall, it has been observed that ozone-containing solutions, that are tempered at a temperature of approximately 40° C.±10° C., may be used advantageously to produce the silicon oxide thin film as part of the second process step of the method described herein.

According to one embodiment, the ozone-containing solution may be adjusted to a pH value of less than 6, preferably to a pH value of between 3 and 4, by adding an acid, preferably hydrochloric acid.

It has been observed that an ozone concentration within the ozone-containing solution may be more easily and/or stably maintained at a desired level if the ozone-containing solution is slightly acidic. A desired pH value may easily be adjusted by dosing hydrochloric acid (HCl). The pH value of the ozone-containing solution may be adjusted and/or measured before or during production of the silicon oxide thin film. A suitable sensor for measuring the pH value of the oxidising liquid may be provided in the oxidation assembly for this purpose. The oxidation assembly may also comprise, for example, an acid reservoir and a dosing pump, whose operation is controlled or regulated, for example, taking into account the pH value measured by the sensor.

According to one embodiment, the partial surface of the solar cell substrate may be treated with the oxidising liquid for a process time of between 1 second and 300 seconds, preferably between 50 seconds and 180 seconds.

In other words, process parameters during oxidation of the partial surface of the solar cell substrate may be adjusted so that a silicon oxide thin film with desired properties, in particular a desired thickness and/or homogeneity, is produced within relatively short process times. For this purpose, process parameters such as the concentration of the ozone-containing solution and its temperature may be suitably adjusted. Therein, the shorter a process time achieved may be, that is to say, the faster the silicon oxide thin film may be produced by treatment with the oxidising liquid, the shorter, for example, a length of the oxidation liquid bath and/or the higher the speed of transport through the oxidation liquid bath may be. Overall, a necessary length of the wet bench may be kept small and/or the throughput achievable with the wet bench may be kept high through suitable selection of process parameters and the short process time that these allow.

According to one embodiment, in process step (ii), the silicon oxide thin film may be produced on the partial surface of the solar cell substrate in a sequential manner by treating the partial surface with a first ozone-containing solution contained in a first bath and then treating the partial surface with a second ozone-containing solution contained in a second bath.

In other words, the silicon oxide thin film may be generated in a two-stage process. Different ozone-containing solutions may be used in the various process stages. The solutions may differ, for example, with regard to their ozone concentration, temperature and/or other process parameters. Overall, this may allow the silicon oxide thin film to be produced more precisely and/or reliably.

According to one embodiment, the wet bench may comprise in its oxidation assembly at least two oxidation liquid baths each configured to receive an oxidising liquid, the wet bench further comprising, for each of the oxidation liquid baths, parameterisation devices configured to adjust process parameters relating to the oxidising liquid in the respective oxidation liquid bath within predefined ranges during the oxidation process.

The two oxidation liquid baths may be disposed one after the other along a conveying direction in which the conveying system moves the solar cell substrates. Coming from the etching assembly, a solar cell substrate thus first passes through a first oxidation liquid bath and then through a second oxidation liquid bath. With the aid of the parameterisation devices, differently parameterised oxidising liquids, for example, ozone solutions at different concentrations and/or temperatures, may be present in each of the two baths.

In the embodiment of the processing method described above, in process step (i) the partial area of the emitter layer and the partial area of the silicate glass layer covering it may be removed by means of a one-stage etching process in an etching liquid. A solution that etches both the silicon of the emitter layer and the silicon oxide of the silicate glass layer may be used as the etching liquid. For example, a solution containing both hydrofluoric acid (HF) and oxidising nitric acid (HNO₃) may be used for this purpose. In this embodiment, it may be sufficient to provide a single etching liquid bath in the etching assembly.

However, an etching process step configured in this way may have a number of disadvantages in an industrial application. For example, the process step may be very harmful to the environment due to a high nitrate load associated with it, and/or may involve complex handling due to, among other things, a need to discharge nitrous gases (NOx) and waste water and to take extensive safety precautions and ensure strict personal protection. Furthermore, a layer of porous silicon may form, which usually has to be etched back before subsequent process steps are carried out.

According to one embodiment, as an alternative to a single-stage etching process, in process step (i) the edge isolation process may be configured as a two-stage process with a first process stage and a second process stage. In the first process stage, the partial area of the silicate glass layer may be removed by treating the surface of the solar cell substrate with an etching liquid containing hydrofluoric acid. In the second process stage, the partial area of the emitter layer may be removed by treating the surface of the solar cell substrate with a basic etching liquid.

In other words, the edge isolation process may be carried out by a two-stage etching process. In the first process stage, only the silicate glass layer above the part of the emitter layer to be removed is etched away by treating it with an etching liquid that attacks only the silicate glass layer, but not silicon. For example, an etching liquid containing only hydrofluoric acid but not an oxidising substance such as nitric acid may be used for this purpose. Hydrofluoric acid etches the silicon oxide of the silicate glass layer, but not the silicon in the emitter layer. The solar cell substrates may be held or guided in such a way that they come into contact with the etching liquid containing hydrofluoric acid on only one side, so that the silicate glass layer on the opposite surface remains unetched.

In the second process stage, mainly the emitter layer in the partial area previously freed from the silicate glass layer is then selectively etched away by treating it with an etching liquid that essentially attacks only silicon, but does not etch the silicate glass layer or at most does so only slightly or slowly, so that the silicate glass layer retains at least a residual thickness after the etching step of the second process stage. A basic etching solution such as, for example, a potassium hydroxide solution (KOH), a sodium hydroxide solution (NaOH) or a tetramethylammonium hydroxide solution (TMAH) may be used for this purpose. This may be heated to process temperatures typically between 6° and 85° C.

The liquids used in the proposed two-stage process, as well as their waste products, are generally much easier to handle or remove than those used in the single-stage process described above. Furthermore, alkaline etched surfaces are usually smoother and therefore more suitable for subsequent formation of a tunnel oxide layer than acid etched surfaces.

In order to carry out such a two-stage process, according to one embodiment the etching assembly may further comprise an additional etching liquid bath configured to receive a basic etching liquid, for example containing potassium hydroxide, by means of which at least a partial area of the emitter layer on the solar cell substrate is to be removed as part of the edge isolation process by treating the surface of the solar cell substrate with the etching liquid containing potassium hydroxide in the etching process. In this case the wet bench furthermore has parameterisation devices configured to adjust process parameters relating to the etching liquid containing potassium hydroxide in the additional etching liquid bath within predetermined ranges during the etching process.

The additional etching liquid bath may be located between a preceding etching liquid bath and a subsequent oxidation liquid bath. As a parameterisation device, this additional etching liquid bath may in particular have a heater in order to heat etching liquid containing potassium hydroxide contained therein. A temperature sensor may also be provided to monitor the temperature of the etching liquid.

According to a more specific embodiment, after the second process stage and before the silicon oxide thin film is produced, metal ions may be removed by treating the surface of the solar cell substrate with a further etching liquid containing hydrofluoric acid and hydrochloric acid.

In other words, after the emitter layer has been etched away in the partial area previously freed from the silicate glass layer in the second process stage, the solar cell substrate may be cleaned of residues in the form of metal ions. For this purpose, the solar cell substrate may be brought into contact with a low-concentration etching liquid. The further etching liquid used for this purpose may contain hydrofluoric acid but be free of oxidising media, in particular free of nitric acid. This further etching liquid may also contain hydrochloric acid.

According to one embodiment, the wet bench may further comprise, in its etching assembly, an additional etching liquid bath configured to receive the etching liquid containing hydrofluoric acid and hydrochloric acid by means of which metal ions are to be removed by treating the surface of the solar cell substrate in the etching process. In addition, the wet bench may also comprise parameterisation devices configured to adjust process parameters relating to the etching liquid containing hydrofluoric acid and hydrochloric acid in the additional etching liquid bath within predetermined ranges during the etching process.

It is noted that possible advantages and embodiments of the invention are described herein partly with reference to a processing method according to the invention and partly with reference to a wet bench according to the invention. A person skilled in the art will recognise that the described features may be suitably transferred, adapted, interchanged or modified to arrive at further embodiments of the invention.

### BRIEF DESCRIPTION OF DRAWINGS

Embodiments of the invention are described below with reference to the accompanying drawings, in which neither the drawings nor the description are to be construed as limiting the invention.

FIG. 1 shows a longitudinal section view of a wet bench according to an embodiment of the invention.

FIG. 2 illustrates steps of a processing method according to an embodiment of the invention.

The figures are merely schematic and not to scale. Identical reference signs in the different figures denote identical or identically acting features.

### DETAILED DESCRIPTION

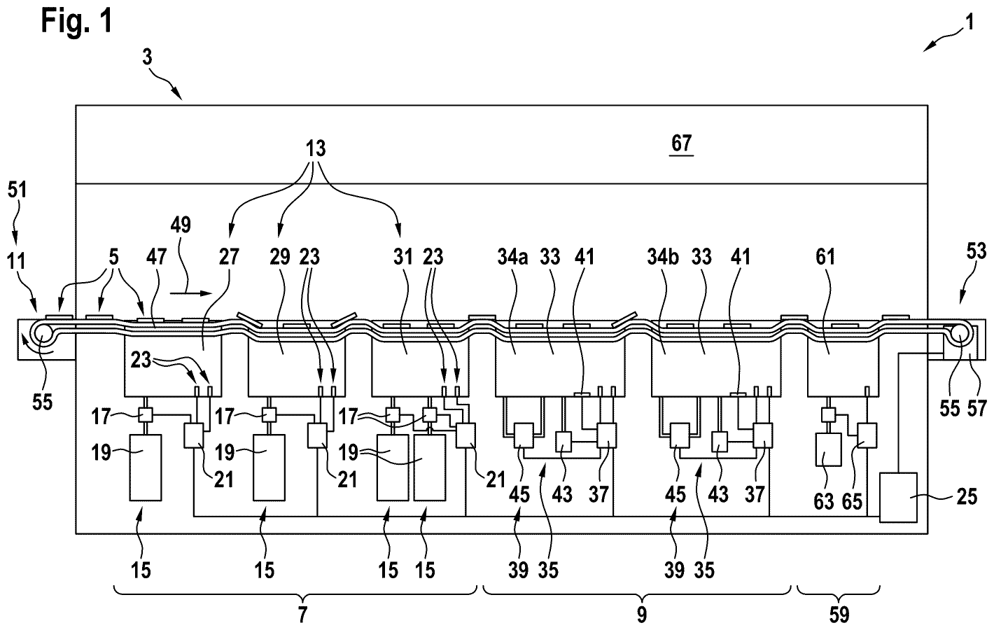

FIG. 1 shows a wet bench 1. The wet bench 1 serves as a processing apparatus 3 for processing a plurality of solar cell substrates 5.

In particular, the wet bench 1 is configured to etch back solar cell substrates 5 in the form of silicon wafers, on the surface of which an emitter layer and a silicate glass layer covering the emitter layer may have been previously formed, first in partial areas as part of an etching process and if necessary to free them from the emitter layer, and then to produce a silicon oxide thin film on the surface of the solar cell substrates 5 as part of an oxidation process.

In broad terms, the wet bench 1 comprises an etching assembly 7, an oxidation assembly 9 and a conveyor system 11.

In the example shown, the etching assembly 7 comprises three etching liquid baths 13. Each of the etching liquid baths 13 is adapted to receive an etching liquid with which the silicate glass layer and/or the emitter layer may be etched. Each etching liquid bath 13 is connected to at least one parameterisation device 15 which may adjust process parameters of the respective etching liquid in the etching liquid bath 13 in a desired manner during an etching process. For this purpose, the parameterisation device 15 may, for example, have a dosing device 17 with the aid of which concentrated etching liquid coming from a reservoir 19 may be introduced into the respective etching bath 13. The dosing device 17 may be controlled or regulated by a control unit 21. The control unit 21 may be connected to sensors 23 such as, for example, a concentration sensor to measure the concentration of the etching liquid in the etching bath 13 and/or a temperature sensor to measure the temperature of the etching liquid in the etching bath 13. Furthermore, each of the control units 21 may be connected to a central controller 25 of the wet bench 1.

In the illustrated wet bench 1, a first etching liquid bath 27 is provided to receive an etching liquid containing hydrofluoric acid, said etching liquid being free of oxidising substances such as, for example, nitric acid. The associated parameterisation device 15 is adapted to adjust process parameters such as, for example, a concentration, a temperature, etc. for this etching liquid containing hydrofluoric acid in the etching liquid bath 27.

A further second etching liquid bath 29 is provided to receive a basic etching liquid, for example containing potassium hydroxide. The associated parameterisation device 15 is used to adjust process parameters such as, for example, a concentration, a temperature, etc. for this etching liquid containing potassium hydroxide in the etching liquid bath 29. As well as being connected to sensors 23, an associated control unit 21 may control a heating device (not shown) to heat the etching liquid to an elevated temperature of, for example, between 60° C. and 85° C.

An additional third etching liquid bath 31 is provided to receive an etching liquid containing hydrofluoric acid and hydrochloric acid. For this purpose, the associated parameterisation device 15 may comprise two dosing devices 17 for dosing concentrated hydrofluoric acid on the one hand and concentrated hydrochloric acid on the other hand from respective reservoirs 19 into the etching liquid bath 31.

In the example shown, the oxidation assembly 9 comprises two oxidation liquid baths 33. The oxidation liquid baths 33 are adapted to receive an oxidising liquid. Each oxidation liquid bath 33 is connected to an associated parameterisation device 35, with the aid of which process parameters relating to the oxidising liquid in the respective oxidation liquid bath 33 may be adjusted during an oxidation process.

In this case, the parameterisation device 35 may comprise a control unit 37 which, by means of sensors 23, may acquire information about current process parameters such as concentrations, temperatures, pH values, etc. in the respective oxidation liquid bath 33. The control unit 37 may then suitably control a dosing device 39 in order to suitably adjust the concentration of oxidising liquid. Furthermore, the control unit 37 may suitably control a tempering device 41 to suitably adjust the temperature of the oxidising liquid. In addition, an acid metering device 43 may be controlled via the control unit 37, with the aid of which a pH value of the liquid in the oxidation liquid bath 33 may be maintained at a desired level. The process parameters may be adjusted differently in a first bath 34a of the oxidation liquid baths 33 and in a second bath 34b of the oxidation liquid baths 33.

For example, the oxidation liquid bath 33 may be associated with an ozone generator 45 configured to enrich the liquid in the oxidation liquid bath 33 with ozone to form an oxidising ozone-containing solution.

The parameterisation device 35 may be adapted, by suitably controlling the ozone generator 45, to adjust the ozone-containing solution with an ozone concentration in a range from 0.1 ppm to 70 ppm, preferably between 25 ppm and 40 ppm. Furthermore, the temperature of the ozone-containing solution may preferably be kept within a range of 0° C. to 60° C., preferably below 50° C., by suitably controlling the tempering device 41. Furthermore, the pH value may be maintained in a range of 3 to 4 by suitably controlling the acid metering device 43.

The conveyor device 11 is configured to move the solar cell substrates 5 sequentially, that is to say, one after the other, first through the etching assembly 7 and then through the oxidation assembly 9. For this purpose, the conveyor device 11 may have a plurality of transport rollers (not shown for the sake of clarity), at least some of which may be actively driven. The solar cell substrates 5 may be moved by means of the transport rollers in a conveying direction 49 from an inlet 51 of the wet bench 1 along a conveying path towards an outlet 53 of the wet bench, while passing through the various etching liquid baths 13 and oxidation liquid baths 33.

Alternatively, it is also conceivable to move the solar cell substrates 5 along the conveying path by means of a circulating conveyor belt 47 on which the solar cell substrates 5 may be deposited and which moves in the conveying direction 49 from the inlet 51 of the wet bench 1 along the etching assembly 7 and then along the oxidation assembly 9 towards the outlet 53 of the wet bench, thereby guiding the solar cell substrates 5 through the different etching liquid baths 13 and oxidation liquid baths 33. Where appropriate, the conveyor belt 47 may be of a width that allows a plurality of solar cell substrates 5 to be placed on it next to each other transversely to the conveying direction 49. Each solar cell substrate 5 may thus be part of one of a plurality of rows or tracks made up of solar cell substrates 5 disposed one after the other in the conveying direction 49. The conveyor belt 47 may be deflected by pulleys 55, at least one of these pulleys 55 being driven by a drive 57.

In principle, it is possible to configure the conveyor device 11 in such a way that solar cell substrates 5 between two adjacent baths are each raised above an edge of the baths and then lowered again to or below the local liquid level when the adjacent bath is reached. Alternatively, however, it is also possible to configure the wet bench 1 and its conveyor device 11 in such a way that the conveyor path runs horizontally along a plane, for example with the aid of weirs and squeegee rollers.

The conveyor device 11 may guide the solar cell substrates 5 through the various baths 13, 33 at a conveying speed determined by the drive 57. In this case, a length of the baths 13, 33 along the conveying direction 49 determines the length of time a solar cell substrate 5 spends in a liquid contained in the respective bath. The length of the oxidation liquid baths 33 may preferably be dimensioned such that, in relation to a predetermined conveying speed, a process duration within which the solar cell substrate 5 is guided through the oxidation liquid baths 33 and is oxidised there by the oxidising liquid is shorter than 300 seconds, preferably shorter than 180 seconds.

In addition, the wet bench 1 shown by way of example has a rinsing assembly 59 with a rinsing bath 61 into which rinsing liquid, such as deionised water, for example, coming from a reservoir 63 or a pipe and controlled by a control unit 65, may be introduced. Each process step may possibly be followed by a corresponding rinsing step, for example in order to minimise media carry-over via the solar cell substrates 5. The solar cell substrates 5 may be cleaned with the aid of the rinsing liquid. If necessary, the rinsing assembly 59 may further comprise a drying device (not shown) to subsequently dry the solar cell substrates 5 before they are removed from the wet bench 1 at the outlet 53. An extractor 67 above the etching assembly 7, oxidation assembly 9 and rinsing assembly 59 may extract released gases and/or vapours.

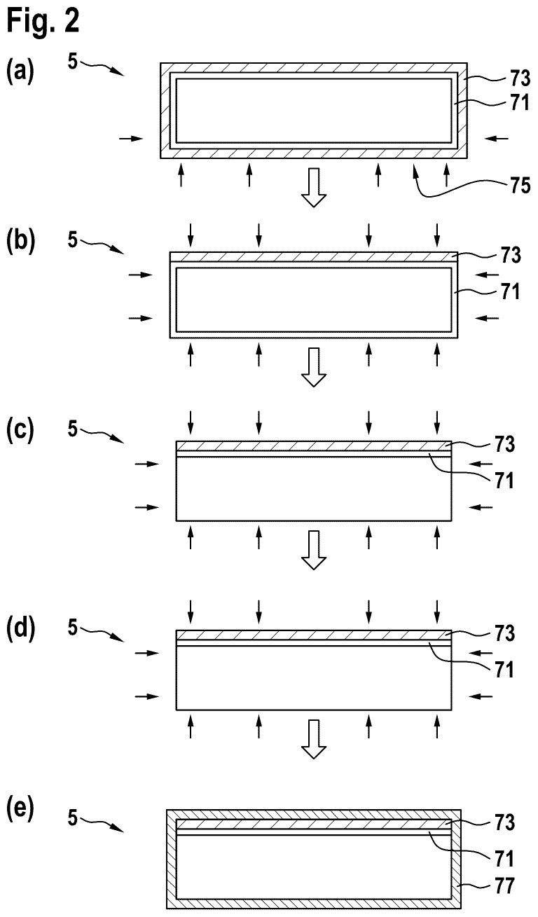

A sequence of process steps (a) to (c), with which solar cell substrates 5 may be processed as they pass through the wet bench 1, is described below with reference to FIG. 2.

In the first process step (a), the solar cell substrate 5 is provided, for example, by placing it on the conveyor device 11 at the inlet 51 of the wet bench 1. The solar cell substrate 5 has preferably already undergone a diffusion process in a hot atmosphere containing dopant. The solar cell substrate 5 consequently has a doped emitter layer 71 on its surface and a silicate glass layer 73 overlying it. Both layers 71, 73 extend along the entire surface of the solar cell substrate 5.

The solar cell substrate 5 is then moved through the etching liquid containing hydrofluoric acid in the first etching liquid bath 27. Therein, the solar cell substrate 5 is guided in such a way that the etching liquid may wet only a downward-facing surface, whereas an opposite, upward-facing surface does not come into contact with the etching liquid (illustrated by small arrows in FIG. 2). The etching liquid containing hydrofluoric acid etches away the silicate glass layer 73 in a partial area 75 on the downward-facing surface of the solar cell substrate 5, whereas on the upward-facing surface the silicate glass layer 73 is retained.

In the second process step (b), the solar cell substrate 5 is then passed through the hot etching liquid containing potassium hydroxide in the second etching liquid bath 29. Therein, the solar cell substrate 5 is completely immersed. The etching liquid containing potassium hydroxide attacks the silicon of the solar cell substrate 5 in the partial area 75 previously freed from the silicate glass layer 73 and removes the emitter layer 71 there. On the upward facing surface, which remains covered by the silicate glass layer 73, the silicate glass layer 73 protects the emitter layer 71 so that it is not removed there.

Next, in the third process step (c), the solar cell substrate 5 is moved through the low-concentration hydrofluoric acid and hydrochloric acid etching liquid in the third etching liquid bath 31. The acids contained therein cause a cleaning step in which metal ions are removed from the surfaces of the solar cell substrate 5.

In the fourth process step (d), the solar cell substrate 5 is then moved through the oxidation liquid baths 33 of the oxidation assembly 9, wherein it is preferably fully immersed in the oxidation liquid bath 33. Since the solar cell substrate 5 is transferred directly from the etching assembly 7 to the oxidation assembly 9, it is not generally possible for oxide to form on its surface in the interim. In other words, the surface of the solar cell substrate 5 previously treated with, among other things, hydrofluoric acid is free of oxides and may be further treated in this state in the oxidation assembly.

The oxidising liquid contained in the oxidation liquid baths 33 causes the formation of a silicon oxide thin film 77 on the surface of the solar cell substrate 5. The silicon oxide thin film 77 has a thickness of a few nanometres at most. The process parameters adjusted in the oxidation assembly 9 may result in the production of a silicon oxide thin film 77 of very high quality, in particular with very high homogeneity and purity.

Finally, in the fifth process step (e) the solar cell substrate 5 treated in this way may be rinsed and dried in the rinsing assembly 59 before it may be removed from the wet bench 1 at the outlet 53.

The solar cell substrate 5 processed in this way may then be further processed with other equipment. In particular, a doped layer of amorphous silicon (a-Si) may be deposited on suitable areas of the solar cell substrate 5 to form passivated contacts. Such an a-Si layer may be deposited on the silicon oxide thin film 77, for example, in an LPCVD, PECVD or APCVD deposition device. The a-Si layer may be converted into a polycrystalline silicon layer within a subsequent annealing step at temperatures of 800° C.-1000° C. The resulting stack consisting of the tunnel oxide layer formed by the silicon oxide thin film 77 and the polycrystalline silicon layer may serve as a passivated contact for a solar cell manufactured according to the TOPCon concept.

Finally, it should be noted that terms such as “having”, “comprising”, etc. do not exclude other elements or steps, and terms such as “one” or “a” do not exclude a plurality. It should further be noted that features or steps that have been described with reference to one of the above embodiments may also be used in combination with other features or steps of other embodiments described above. Reference signs in the claims are not to be considered as limitations.

### LIST OF REFERENCES

1 Wet bench
3 Processing apparatus
5 Solar cell substrates
7 Etching assembly
9 Oxidation assembly
11 Conveyor device
13 Etching liquid bath
15 Parameterisation device
17 Dosing device
19 Reservoir
21 Control unit
23 Sensor
25 Central controller
27 First etching liquid bath
29 Second etching liquid bath
31 Third etching liquid bath
33 Oxidation liquid bath
34a First bath
34b Second bath
35 Parameterisation device
37 Control unit
39 Dosing device
41 Tempering device
43 Acid dosing device
45 Ozone generator
47 Conveyor belt
49 Conveying direction
51 Inlet
53 Outlet
55 Pulley
57 Drive
59 Rinsing assembly
61 Rinsing bath
63 Reservoir
65 Control unit
67 Extractor
71 Emitter layer
73 Silicate glass layer
75 Partial area
77 Silicon oxide thin film

1-22. (canceled)

23. A method of processing a plurality of solar cell substrates, each solar cell substrate comprising a silicon wafer, the method comprising at least the following process steps:
(i) removing at least a partial area of a near-surface layer of the silicon wafer by means of an etching process by treating the surface of the solar cell substrate with an etching liquid, and
(ii) producing a silicon oxide thin film at least on a partial surface of the solar cell substrate by treating the partial surface with an oxidising liquid,
the solar cell substrates being subjected to process steps (i) and (ii) sequentially, one after the other within a single processing apparatus,
wherein the partial surface of the solar cell substrate is treated for a process time of between 1 s and 300 s.

24. The method according to claim 23,
wherein a doped emitter layer and a silicate glass layer covering the emitter layer are disposed on a surface of the silicon substrate,
the method in process step (i) comprising:
removing at least a partial area of the emitter layer as well as a partial area of the silicate glass layer covering this partial area by means of the etching process by treating the surface of the solar cell substrate with an etching liquid.

25. The method according to claim 23,
wherein the solar cell substrates are moved one after the other by means of a common conveyor device of the processing apparatus, first through an etching liquid bath containing the etching liquid and then through an oxidation liquid bath containing the oxidising liquid.

26. The method according to claim 23,
wherein during process steps (i) and (ii) the solar cell substrates are moved at a uniform speed first through the etching liquid and then through the oxidising liquid.

27. The method according to claim 23,
wherein the solar cell substrates remain wetted with liquid at least in some areas during a transfer from process step (i) to process step (ii).

28. The method according to claim 23,
wherein in process step (ii) the silicon oxide thin film is produced on the partial surface of the solar cell substrate by treating the partial surface with an ozone-containing solution.

29. The method according to claim 28,
wherein the ozone-containing solution has an ozone concentration of between 0.1 ppm and 70 ppm, preferably between 1 ppm and 40 ppm, and more preferably between 25 ppm and 40 ppm.

30. The method according to claim 28,
wherein the ozone-containing solution has a temperature of between 0° C. and 60° C., preferably between 20° C. and 50° C. and more preferably between 30° and 45° C.

31. The method according to claim 28,
wherein the ozone-containing solution is adjusted to a pH value of less than 6, preferably to a pH value of between 3 and 4, by adding an acid, preferably by adding hydrochloric acid.

32. The method according to claim 23,
wherein the partial surface of the solar cell substrate is treated for a process time of between 50 seconds and 180 seconds.

33. The method according to claim 23,
wherein in process step (ii), the silicon oxide thin film is produced on the partial surface of the solar cell substrate in a sequential manner by treating the partial surface with a first ozone-containing solution contained in a first bath and then treating the partial surface with a second ozone-containing solution contained in a second bath.

34. The method according to claim 23,
wherein in process step (i) the etching process is configured as a two-stage process with a first process stage and a second process stage,
wherein in the first process stage the partial area of the silicate glass layer is removed by treating the surface of the solar cell substrate with an etching liquid containing hydrofluoric acid, and
wherein in the second process stage the partial area of the emitter layer is removed by treating the surface of the solar cell substrate with a basic etching liquid.

35. The method according to claim 34,
wherein after the second process stage and before the silicon oxide thin film is produced, metal ions are removed by treating the surface of the solar cell substrate with a further etching liquid containing hydrofluoric acid and hydrochloric acid.

36. A wet bench for processing solar cell substrates, the wet bench being configured to carry out or control the method according to claim 23.

37. The went bench according to claim 36, further comprising:
an etching assembly having at least one etching liquid bath for receiving at least one etching liquid, by means of which at least a partial area of a near-surface layer of a silicon wafer is to be removed by means of an etching process by treating the surface of the solar cell substrate with an etching liquid in an etching process, and
an oxidation assembly having at least one oxidation liquid bath for receiving at least one oxidising liquid, by means of which a silicon oxide thin film is to be produced at least on a partial surface of the solar cell substrate by treating the partial surface with the oxidising liquid in an oxidation process, and
a conveyor device for moving the silicon substrates one after the other first through the etching assembly and then through the oxidation assembly,
wherein the oxidation assembly is configured for treating the partial surface of the solar cell substrate for a process time of between 1 s and 300 s.

38. The wet bench according to claim 37,
wherein the solar cell substrate comprises a silicon wafer, on the surface of which the doped emitter layer and the silicate glass layer covering the emitter layer are disposed,
wherein the etching assembly is configured with at least one etching liquid bath for receiving at least one etching liquid, by means of which at least a partial area of the emitter layer on the solar cell substrate and/or a partial area of the silicate glass layer covering this partial area is to be removed by means of the etching process by treating the surface of the solar cell substrate with the etching liquid in an etching process.

39. The wet bench according to claim 37,
wherein the etching assembly comprises at least one etching liquid bath configured to receive an etching liquid containing hydrofluoric acid, and wherein the wet bench further comprises parameterisation devices configured to adjust process parameters relating to the etching liquid containing hydrofluoric acid in the etching liquid bath within predetermined ranges during the etching process.

40. The wet bench according to claim 37,
wherein the oxidation assembly comprises at least one oxidation liquid bath configured to receive the oxidising liquid, and wherein the wet bench further comprises parameterisation devices configured to adjust process parameters relating to the oxidising liquid in the oxidation liquid bath within predetermined ranges during the oxidation process.

41. The wet bench according to claim 40,
wherein the wet bench further includes an ozone generator configured to enrich the oxidising liquid with ozone.

42. The wet bench according to claim 40,
wherein the oxidation assembly comprises at least two oxidation liquid baths each configured to receive an oxidising liquid, and wherein the wet bench further comprises, for each of the oxidation liquid baths, parameterization devices configured to adjust process parameters relating to the oxidising liquid in the respective oxidation liquid bath within predetermined ranges during the oxidation process.

43. The wet bench according to claim 38,
wherein the etching assembly further comprises an additional etching liquid bath configured to receive a basic etching liquid by means of which at least a partial area of the emitter layer on the solar cell substrate is to be removed in the etching process by treating the surface of the solar cell substrate with the etching liquid containing potassium hydroxide in the etching process, and wherein the wet bench further comprises parameterisation devices configured to adjust process parameters relating to the etching liquid containing potassium hydroxide in the additional etching liquid bath within predetermined ranges during the etching process.

44. The wet bench according to claim 37,
wherein the etching assembly further comprises an additional etching liquid bath configured to receive an etching liquid containing hydrofluoric acid and hydrochloric acid by means of which a previously unremoved further partial area of the silicate glass layer is to be removed in the etching process by treating the surface of the solar cell substrate in the etching process, and wherein the wet bench further comprises parameterisation devices configured to adjust process parameters relating to the etching liquid containing hydrofluoric acid and hydrochloric acid in the additional etching liquid bath within predetermined ranges during the etching process.
